(19) United States
(12) Patent Application Publication
(10) Pub. No.: US 2004/0113143 A1
(43) Pub. Date: Jun. 17, 2004

(54) Semiconductor device having a lattice-mismatched semiconductor layer on a substrate

(75) Inventor: Hidetoshi Fujimoto, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/677,224

(22) Filed: Oct. 3, 2003

(30) Foreign Application Priority Data
Oct. 7, 2002 (JP) P2002-294101

(51) Int. Cl. H01L 29/06; H01L 31/0328; H01L 31/109; H01L 31/072; H01L 31/0336

(52) U.S. Cl. 257/22; 257/197; 257/201

(57) ABSTRACT

An indium arsenide (InAs) layer is disposed on a gallium arsenide (GaAs) substrate. A semiconductor layer is disposed over the indium arsenide layer. The semiconductor layer has a lattice constant larger than that of the gallium arsenide substrate and smaller than that of the indium arsenide layer.

### CROSS REFERENCE TO RELATED APPLICATIONS

This application is based upon and claims the benefit of priority from the prior Japanese Patent Application No. P2002-294101, filed on Oct. 7, 2002; the entire contents of which are incorporated herein by reference.

### BACKGROUND OF THE INVENTION

1. Field of the Invention

The present invention relates to a semiconductor device having an epitaxial layer of a compound semiconductor excluding gallium arsenide (GaAs) formed on a GaAs substrate.

2. Description of the Related Art

III-V compound semiconductor, for example GaAs, based transistors have various excellent characteristics such as high operating frequency, low noise, high output, high gain, low operating voltage, high operating efficiency and low power dissipation as compared with silicon (Si) transistors. Due to these characteristics, compound semiconductor based field effect transistors (FETs) and heterojunction bipolar transistors (HBTs) have been put into practice in mobile communication devices. In the FETs and HBTs, attention is being given to HBTs, which have an indium gallium arsenide (InGaAs) layer as a base layer and an indium gallium phosphide (InGaP) layer or an indium phosphide (InP) layer as an emitter layer which lattice-matches with the base layer, because they can decrease an operating voltage.

In HBTs whose base layer is such an InGaAs, the InGaAs layer is generally formed on the InP or InGaP layer lattice-matched with the InGaAs. There is no lattice-matched substrate with InP and the InP layer is usually formed on the InP substrate. It is, however, difficult to enlarge the diameter of the InP substrate, and even InP substrates with small diameter are expensive, namely, the price is at least five times as high as that of the GaAs substrate. For this reason, in HBTs where the InGaAs layer is used as the base layer, the growth of the InP layer or the InGaP layer on the GaAs substrate with a larger diameter and less expensive than the InP substrate has been attempted.

Since a lattice constant difference between the GaAs substrate and the InP layer is about 3.8%, however, it is difficult an InP monocrystal layer directly on the GaAs substrate. Conventionally, the InP layer is, therefore, grown on the GaAs substrate via a linear-graded or a step-graded buffer, whose lattice constant changes from the GaAs substrate to the InP layer. For example, “A Comparative Study of As, Sb and P-based Metamorphic HEMT” 2000 GaAs MANTECH, USA, GaAs MANTECH Inc. p.85-88 written by D. Lubyshev and others can be referenced. Such HBTs including the buffer layer have short operation lives.

### SUMMARY OF THE INVENTION

An aspect of the present invention inheres in a semiconductor device including a gallium arsenide substrate,

an indium arsenide layer disposed on the gallium arsenide substrate, a semiconductor layer disposed over the indium arsenide layer and having a lattice constant larger than that of the gallium arsenide substrate and smaller than that of the indium arsenide layer, and a semiconductor section disposed on the semiconductor layer, lattice-matching with the semiconductor layer and configured to function as a transistor.

Another aspect of the present invention inheres in a wafer including a gallium arsenide substrate, an indium arsenide layer disposed on the gallium arsenide substrate, and a semiconductor layer disposed over the indium arsenide layer and having a lattice constant larger than that of the gallium arsenide substrate and smaller than that of the indium arsenide layer.

Still Another aspect of the present invention inheres in a wafer including a silicon (Si) substrate, a gallium arsenide layer disposed over the silicon substrate, an indium arsenide layer disposed on the gallium arsenide layer, and a semiconductor layer disposed over the indium arsenide layer and having a lattice constant larger than that of the gallium arsenide layer and smaller than that of the indium arsenide layer.

Still Another aspect of the present invention inheres in a method of making a wafer including forming an indium arsenide layer on a gallium arsenide substrate at a first substrate temperature, forming a first semiconductor layer having a first lattice constant larger than that of the gallium arsenide substrate and smaller than that of the indium arsenide layer on the indium arsenide layer at the first substrate temperature, and forming a second semiconductor layer having a second lattice constant larger than that of the gallium arsenide substrate and smaller than that of the indium arsenide layer on the first semiconductor layer at a second substrate temperature higher than the first substrate temperature.

Still Another aspect of the present invention inheres in a method of making a semiconductor device including forming an indium arsenide layer on a gallium arsenide substrate at a first substrate temperature, forming a first semiconductor layer having a first lattice constant larger than that of the gallium arsenide substrate and smaller than that of the indium arsenide layer on the indium arsenide layer at the first substrate temperature, forming a second semiconductor layer having a second lattice constant larger than that of the gallium arsenide substrate and smaller than that of the indium arsenide layer on the first semiconductor layer at a second substrate temperature higher than the first substrate temperature, and forming a semiconductor section on the second semiconductor layer lattice-matching with the second semiconductor layer and configured as a transistor.

Still Another aspect of the present invention inheres in a method of making a semiconductor layer including forming an indium arsenide layer on a gallium arsenide substrate at a first substrate temperature, forming a first semiconductor layer having a first lattice constant larger than that of the gallium arsenide substrate and smaller than that of the indium arsenide layer on the indium arsenide layer at the first substrate temperature, and forming a second semiconductor layer having a second lattice constant larger than that of the gallium arsenide substrate and smaller than that of the indium arsenide layer on the first semiconductor layer at a second substrate temperature higher than the first substrate temperature.

### BRIEF DESCRIPTION OF THE DRAWINGS

FIG. 1 is a schematic sectional view of an HBT of a first embodiment of the present invention.

FIG. 2 is a schematic sectional view of an HBT of a second embodiment of the present invention.

FIG. 3 is a schematic sectional view of an HBT of a third embodiment of the present invention.

FIG. 4 is a schematic sectional view of an HEMT of a fourth embodiment of the present invention.

FIG. 5 is a schematic sectional view of a wafer of a fifth embodiment of the present invention.

FIG. 6 is a schematic sectional view of an HBT of a sixth embodiment of the present invention.

FIG. 7 is a schematic sectional view of a wafer of a seventh embodiment of the present invention.

### DETAILED DESCRIPTION OF THE INVENTION

Various embodiments of the present invention will be described with reference to the accompanying drawings. It is to be noted that the same or similar reference numerals are applied to the same or similar parts and element throughout the drawings, and the description of the same or similar parts and elements will be omitted or simplified.

A transistor having an InP layer or the like formed on a GaAs substrate has a short life. The reason for this phenomenon will be considered first. A buffer layer may cause this short life problem. Using a general buffer layer, a base region and an emitter region in addition to a collector region have strains induced therein by the buffer layer due to a lattice constant difference between the GaAs substrate and the InP layer. For this reason, in reliability test of the transistor, the transistor is considered to deteriorate due to the strain in the collector region and the like.

The lattice constant of the GaAs substrate is smaller than that of the InP layer provided on the GaAs substrate, and the InP layer is compressed and strained. In HBTs, a collector region and the like having a thick layer of about 1 to 2 μm is disposed on the GaAs substrate, so the thick layers are compressed and strained. Just after making the transistor, the thick layer can maintain a strained crystalline structure. Temperature of the collector region and the like, however, rises due to electrical operation of the transistor. A stress is applied to the thick layer. The strain becomes large after the transistor is made. Dislocation occurs in the collector region and the like. Thus, consideration should be given to reducing the strain of the crystalline structure in the collector region and the like of the transistor just after the transistor has been made.

(First Embodiment)

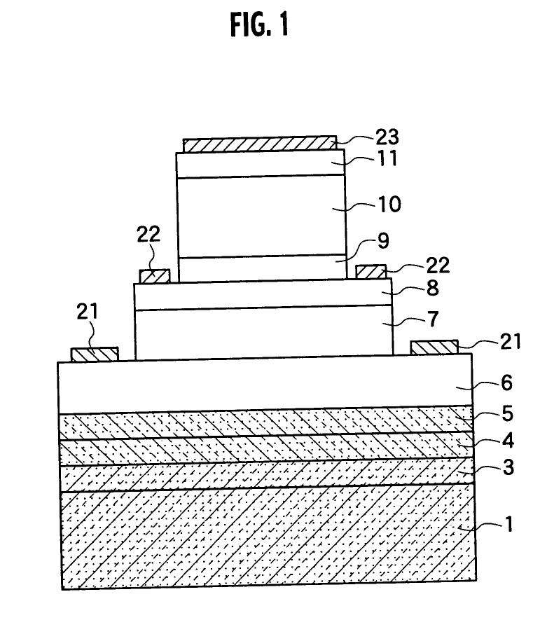

In a double heterojunction bipolar transistor (DHBT) of a first embodiment of the present invention, as shown in FIG. 1, an InAs buffer layer 3, a low-temperature grown InP layer 4, a high-temperature grown InP layer 5, an n-type InGaAs collector contact layer 6, an undoped InP collector layer 7, a p-type InGaAs base layer 8, an n-type InP emitter layer 9, an n-type InP emitter contact layer 10, and an n-type InGaAs emitter contact layer 11 are multilayer in the given order on a semi-insulating GaAs substrate 1.

The thickness of the InAs buffer layer 3 is about 1 nm. The InAs buffer layer 3 buffers strain which occurs due to lattice mismatch between the GaAs substrate 1 and the InP layers 4 and 5. The thickness of the InAs buffer layer 3 is desirably 10 nm or less, more preferably 3 nm or less. When the thickness is too thick, dislocation occurs in the InAs buffer layer 3, and the dislocation is enlarged by deposition of the InP layers 4 and 5 as upper layers, and this dislocation spreads also on the InP layers 4 and 5. The thickness of the InAs buffer layer 3 may be less than 1 nm. That is to say, an In monatomic layer provided on an As monatomic layer on the surface of the GaAs substrate 1 and the As monatomic layer provided on the In monatomic layer may compose the InAs buffer layer 3.

The thickness of the low-temperature grown InP layer 4 is 20 nm. The thickness of the high-temperature grown InP layer 5 is 0.5 μm. The thickness of the n-type InGaAs collector contact layer 6 is 0.5 μm, and its carrier concentration is 2×10¹⁹ cm⁻³. The thickness of the undoped InP collector layer 7 is 10 nm. The thickness of the p-type InGaAs base layer 8 is 50 nm, and its carrier concentration is 4×10¹⁹ cm⁻³. The thickness of the n-type InP emitter layer 9 is 20 nm, and its carrier concentration is 3×10¹⁷ cm⁻³. The thickness of the n-type InP emitter contact layer 10 is 100 nm, and its carrier concentration is 2×10¹⁸ cm⁻³. The thickness of the n-type InGaAs emitter contact layer 11 is 100 nm, and its carrier concentration is 3×10¹⁹ cm⁻³.

A collector electrode 21 is provided on the n-type InGaAs collector contact layer 6. A base electrode 22 is provided on the p-type InGaAs base layer 8. An emitter electrode 23 is provided on the n-type InGaAs emitter contact layer 11. The collector electrode 21, the base electrode 22, and the emitter electrode 23 are ohmic electrodes.

The InAs buffer layer 3 is allowed to intervene between the GaAs substrate 1 and the InP layers 4 and 5 or the InGaP layer. As for lattice constants of respective materials here, the lattice constant of GaAs in the substrate 1 is 0.5653 nm, the lattice constants of InP in the semiconductor layers 4 and 5 are 0.5869 nm, and the lattice constant of InAs in the InAs buffer layer 3 is 0.6058 nm. The lattice constant of InGaP changes according to a mole fraction “x” of In to Ga in InGaP. The mole fraction “x” here is denoted by InₓGa₁₋ₓP (0<x<1). When the mole fraction “x” is 0.48, the lattice constant of InGaP is equal to the lattice constant of GaAs. When the mole fraction “x” is larger than 0.48, the lattice constant of InGaP is larger than the lattice constant of GaAs. As the mole fraction “x” is closer to 1, the composition reaches InP, and thus the lattice constant reaches the lattice constant of InP.

When the InP layers 4 and 5 or the InGaP layer having a mole fraction “x” larger than 0.48 are (is) formed on the GaAs substrate 1, compressive strain occurs in the InP layers 4 and 5 or the InGaP layer. Therefore, the InAs buffer layer 3, having a lattice constant larger than those of GaAs and InP, is inserted between the GaAs substrate 1 and the InP layers 4 and 5 or the like. A substantial amount of dislocation occurs inside or in an interface of the InAs buffer layer 3. This is because the lattice constants differ to an extent that exceeds a limit of the compressive strain. Due to the occurrence of the dislocation, the strain is buffered, and thus the InP layers 4 and 5 which are formed on the InAs buffer layer 3 are substantially uninfluenced by the lattice constant of the GaAs substrate 1 as an underlying layer. The compressive strain of the InP layers 4 and 5, which occurs when the InP layers or the like are formed on the GaAs substrate 1, is buffered. As compared with DHBT in which the InAs buffer layer 3 is omitted and the low-temperature InP layer 4 is provided, the life of a DHBT of the first embodiment is improved by 30%. An HBT with a long life can be formed on the inexpensive GaAs substrate 1.

A method of fabricating a DHBT of the first embodiment is explained below.

(a) The layers 3 to 11 are grown on the GaAs substrate 1 by metal-organic chemical vapor deposition (MOCVD). The following source materials are used for growth. Trimethylgalllium (TMG, (CH₃)₃Ga), triethylgallium (TEG, (C₂H₅)₃Ga), and trimethylindium (TMI, (CH₃)₃In) are used as Group III source materials. Hydrogen (H₂) is used as a carrier gas of the Group III source materials. The Group III source materials are bubbled by hydrogen, i.e., treated by a hydrogen process, prior to introduction to the reaction chamber. Arsine (AsH₃) gas and phosphine (PH₃) gas are used as Group V source materials. Silane (SiH₄) gas and diethyltellurium (DETe, (C₂H₅)₂Te) are used as source materials for doping of the n-type layers. Carbon tetrabromide (CBr₄) is used as a doping material for the p-type layers. Hydrogen is used also as a carrier gas of the Group V source materials and the source materials used for doping. The respective layers 3 to 11 are grown under conditions such that total flow rate of the respective source materials and the carrier gas in a reaction tube is 0.166 (L/s), and a pressure in the reaction tube or chamber is reduced to about 10000 Pa.

(b) The semi-insulating GaAs substrate 1 has a resistivity of at least 10⁷ Ωcm. The main surface of the substrate 1 is inclined by about 2° in a direction of the <110> surface from a (100) surface and is put on a susceptor in a MOCVD system. The susceptor includes an auxiliary heater. Heating methods include resistance heating, induction heating using an RF coil, lamp heating and the like, but any heating method can be used. In the first embodiment, a lamp heating method is used. As explained below, temperature is detected by a thermocouple attached to the susceptor, i.e., and therefore the detected temperature corresponds to a so-called susceptor temperature. The susceptor temperature is different from the temperature of the surface of the GaAs substrate 1, i.e., so-called substrate temperature. However, when the pressure and the total flow rate in the reaction tube are constant, the susceptor temperature rises and the substrate temperature also rises. Specifically, a one-to-one correlation in temperature is established.

(c) The susceptor temperature is raised to about 650° C. The ambient in the reaction tube is set to an AsH₃ ambient for about 10 minutes. The pressure in the reaction tube is set to about 20000 Pa. As a result, an oxide film or the like on the surface of the GaAs substrate 1 is removed.

(d) The susceptor temperature is dropped to 350° C. while the ambient in the reaction tube is still an AsH₃ ambient. When the susceptor temperature is 350° C., supply of AsH₃ gas is stopped. TMI gas is supplied, and then PH₃ gas is supplied to the reaction tube. As a result, the InAs buffer layer 3 and the low-temperature InP layer 4 are grown. After the supply of AsH3 gas is stopped, TMI gas is supplied, thereby forming the InAs buffer layer 3 on the surface of the GaAs substrate 1 covered with As atoms. Just after the low-temperature InP layer 4 is deposited, it is a polycrystalline layer. Further, the “AsH₃ ambient” is such that As atoms can be supplied to the carrier gas to an extent that As atoms is not evaporated from a substrate including As atoms, such as the GaAs substrate 1. The As atoms are supplied by the thermal decomposition of AsH3. Also following “PH₃ ambient” is such that P atoms can be supplied to the carrier gas to an extent that P atom is not evaporated from a substrate including P atoms.

In the first embodiment, the InAs buffer layer 3 is formed by displacing atoms on the surface of the GaAs substrate 1 by In atoms. The forming method is not limited to the above-described method, and the InAs buffer layer 3 can also be formed by injecting TMI gas as the In source material and AsH₃ gas as the As source material. In this case, the InAs buffer layer 3 with a larger thickness can be formed.

Further, the susceptor temperature at the time of growing the InAs buffer layer 3 is 450° C. or less, more desirably 400° C. or less. When the temperature is higher than 450° C., i.e., 500° C., corrugation occurs on the surface, which is considered to be caused by the surface reaction of the InAs.

(e) The susceptor temperature is raised to 650° C. while the ambient in the reaction tube is still the PH₃ ambient. At the susceptor temperature of 650° C., TMI gas is supplied so that the high-temperature InP layer 5 is formed. The surface of the low-temperature InP layer 4 that was polycrystalline at the step of rising the temperature becomes monocrystalline. The low-temperature InP layer 4 serves as seed crystal in making the high-temperature InP layer 5.

(f) AsH₃, PH₃, TMG, TMI, and SiH₄ gases are used so that the n-type InGaAs collector contact layer 6 and the undoped InP collector layer 7 are formed at the susceptor temperature of 650° C.

(g) The susceptor temperature is dropped to 475° C. in the PH₃ ambient. After the susceptor temperature is stable at 475° C., the Group V source material gas is converted into AsH₃. AsH₃ gas is introduced. Further, TEG, TMI and CBr₄ gases are supplied to the reaction chamber. Thus, the p-type InGaAs layer 8 is formed.

(h) The susceptor temperature is raised to 560° C. in the AsH₃ ambient. After the susceptor temperature is stable at 560° C., the Group V source material gas is converted into PH₃ gas. Further, TMI and SiH₄ gases are supplied to the reaction chamber. Thus, the n-type InP layer 9 and the n-type InP layer 10 are formed.

(i) The susceptor temperature is dropped to 450° C. in the PH₃ ambient. After the susceptor temperature is stable at 450° C., AsH₃ gas is supplied as the Group V source material gas to the reaction chamber. Further, TEG, TMI, and DETe gas are also supplied to the reaction chamber. The n-type InGaAs layer 11 is formed.

(j) After the n-type InGaAs layer 11 is formed, the supplies of all the source materials are stopped. The susceptor temperature is dropped to room temperature in a H₂ ambient. After the ambient is converted to a nitrogen (N₂) ambient, the GaAs substrate 1 where the crystal is grown is taken out from the MOCVD system.

(k) The InGaAs layers 8 and 11 and the GaAs layer can be etched and selectively removed from the InP layers 7, 9 and 10 by a mixed solution of phosphoric acid (H₃PO₄), hydrogen peroxide (H₂O₂) and pure water (H₂O). The InP layers 7, 9 and 10 can be etched and selectively removed from the InGaAs layers 6 and 8 by a mixed solution of hydrochloric acid (HCl) and pure water. The n-type InGaAs collector contact layer 6 and the p-type InGaAs base layer 8 are exposed by application of the mixed solutions. An etching stop layer or the like, which is necessary for the manufacturing process can be suitably arranged between the layers 3 to 11.

(l) The ohmic electrodes 21 to 23 are suitably formed on the exposed n-type InGaAs collector contact hole 6, p-type InGaAs base layer 8, and n-type InGaAs emitter contact layer 11 by using a lift-off process. As metal materials of the collector electrode 21 and the emitter electrode 23, a laminated structure of gold (Au)/germanium (Ge)/nickel (Ni) is used. As a metal material of the base electrode 22, a laminated structure of titanium (Ti)/platinum (Pt)/Au can be used.

(m) A plurality of DHBTs formed on the GaAs substrate 1 are separated and divided. Each of the DHBTs is arranged on supporting substrates made of aluminum nitride (AlN), which is separately prepared for mounting the DHBT thereon. The DHBT elements which are arranged on the supporting substrates, are combined with each other so as to be connected. The connected elements undergo further process, such as molding. In such a manner, the manufacturing process of the semiconductor device is completed.

In the first embodiment, the semi-insulating GaAs substrate in which the main surface is inclined by 2° to the <110> direction from the (100) surface is used as the GaAs substrate 1. It is desirable to use a GaAs substrates, in which the main surface is approximately the (100) surface, i.e., no inclination, through GaAs substrates, in which the main surface is inclined by about 8° in the <110> direction from the (100) surface. Particularly, it is desirable to use GaAs substrates in which the main surface is approximately the (100) surface, i.e., the inclination is less than 1°. This is because the low-temperature InP layer 4 is in the polycrystalline state just after the growth, and the low-temperature InP layer 4 is easily formed on the GaAs substrate 1 with excellent evenness with a wide terrace and sites to which atoms may attach are substantially unavailable. On the other hand, when a range of the inclination is 6° to 8°, even if the flow rate of the doping gas is reduced, a predetermined carrier concentration can be obtained. As a result, the flow rate of the doping gas can be reduced.

As explained above, according to first embodiment, HBTs, each having an InGaAs base layer 8 and operating with a low voltage, can be provided on the comparatively inexpensive GaAs substrate 1 having an enlarged diameter.

In the first embodiment, the emitter layer 9 is made of InP, but an InAlAs layer which lattice-matches with the InGaAs base layer can be used. This layer can change the ratio of energy barrier between a conduction band and a valence band, and thus, the device characteristics can be controlled according to device specifications that differ with application fields.

(Second Embodiment)

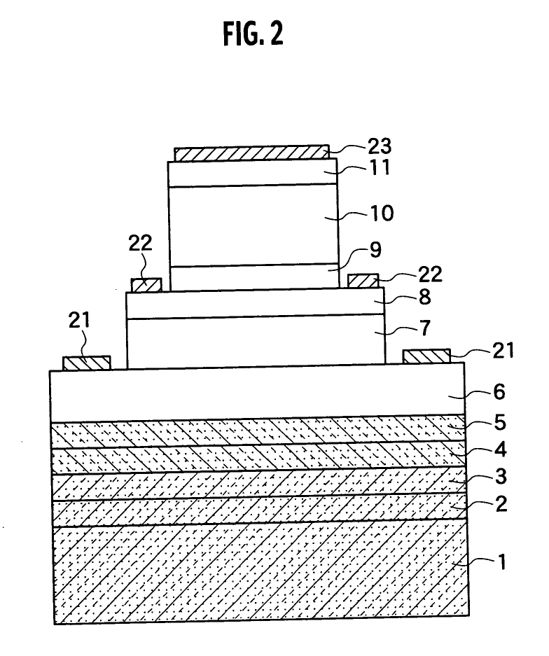

In a DHBT of a second embodiment of the present invention, as shown in FIG. 2, in addition to the structure of DHBT in the first embodiment shown in FIG. 1, a GaAs layer 2 is inserted between the semi-insulating GaAs substrate 1 and the InAs buffer layer 3. The thickness of the GaAs layer 2 is 40 nm. Quality of a GaAs surface as an interface between the GaAs layer 2 and the InAs buffer layer 3 is improved with this arrangement. Crystallinity of the GaAs surface is improved, and a uniform InAs buffer layer 3 can be obtained. As a result, the life of the DHBT is improved by about 30% as compared with the DHBT of the first embodiment.

The DHBT fabricating method according to the second embodiment is explained below.

(a) The source materials are the same as in the first embodiment.

(b) The semi-insulating GaAs substrate 1, having a resistivity of at least 10⁷ Ωcm and a main surface inclined by about 2° in the <110> direction from the (100) surface, is put on the heatable susceptor in the MOCVD system.

(c) The susceptor temperature is raised to about 650° C. The ambient in the reaction tube is set to an AsH₃ ambient for about 10 minutes. The pressure in the reaction tube is set to about 20000 Pa. As a result, an oxide film or the like present on the surface of the GaAs substrate 1 is removed.

(d) TMG gas is supplied so that the GaAs layer 2 is grown. The pressure in the reaction tube at the time of the growth is about 20000 Pa.

(e) The method of forming the laminated structure and the electrode processing are the same as in the first embodiment.

(Third Embodiment)

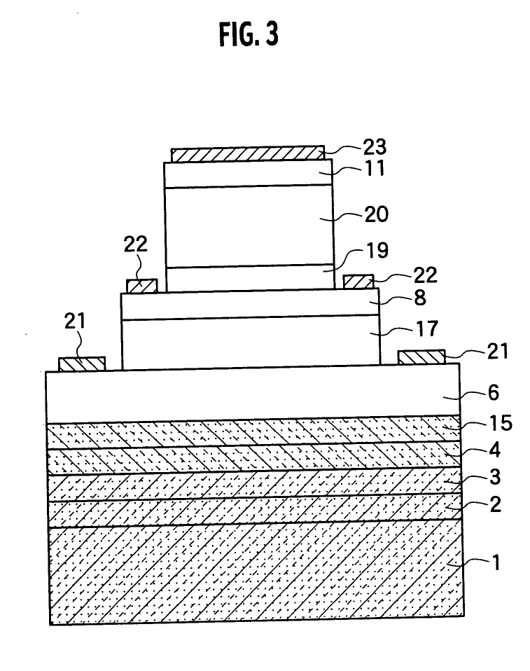

In a single heterojunction bipolar transistor (SHBT) according to a third embodiment of the present invention, as shown in FIG. 3, the GaAs layer 2, the InAs buffer layer 3, the low-temperature grown InP layer 4, a high-temperature grown InGaP layer 15, the n-type InGaAs collector contact layer 6, an n-type InGaAs collector layer 17, the p-type InGaAs base layer 8, an n-type InGaP emitter layer 19, an n-type InGaAs emitter contact layer 20, and the n-type InGaAs emitter contact layer 11 are laminated in the stated order on the semi-insulating GaAs substrate 1.

The thickness of the GaAs layer 2 is about 50 nm. The thickness of the InAs buffer layer 3 is about 1 nm. The thickness of the low-temperature grown InP layer 4 is 20 nm. The thickness of the high-temperature grown InGaP layer 15 is 1 μm. A mole fraction of In in the n-type InGaAs collector contact layer 6 is 15%. The layer 6 has a thickness of 0.5 μm, and a carrier concentration of 3×10¹⁸ cm⁻³. A mole fraction of In in the n-type InGaAs collector layer 17 is 15%. The layer 17 has a thickness of 0.7 μm, and a carrier concentration of 1×1016 cm⁻³. A mole fraction of In in the p-type InGaAs base layer 8 is 15%. The layer 8 has a thickness of 80 nm, and a carrier concentration of 3×10¹⁹ cm⁻³. A mole fraction of In in the n-type InGaP emitter layer 19 is 56%. The layer 19 has a thickness of 25 nm, and a carrier concentration of 3×10¹⁷ cm⁻³. A mole fraction of In in the n-type InGaAs emitter contact layer 20 is 15%. The layer 20 has a thickness of 50 nm, and a carrier concentration of 2×10¹⁸ cm⁻³. A mole fraction of In on the surface of the n-type InGaAs emitter contact layer 11 is 70%, a thickness of 100 nm, and a carrier concentration of 3×10¹⁹ cm⁻³. The n-type InGaAs emitter contact layer 11 has an inclined region where the mole fraction of In is changed in an incline range of 15% to 70%, and a uniform region where the mole fraction is uniform. Thickness of the respective regions can be suitably divided. In the third embodiment, the thickness of the inclined region and the uniform region is 50 nm.

The collector electrode 21 is provided on then-type InGaAs collector contact layer 6. The base electrode 22 is provided on the p-type InGaAs base layer 8. The emitter electrode 23 is provided on the n-type InGaAs emitter contact layer 11. The collector electrode 21, the base electrode 22, and the emitter electrode 23 are ohmic electrodes.

A SHBT forming method of the third embodiment is explained below.

(a) The source materials are the same as in the first embodiment.

(b) In the semi-insulating GaAs substrate 1, the resistivity is at least 10⁷ Ωcm. The main surface inclines by 2° in the <110> direction from the (100) surface. The semi-insulating GaAs substrate 1 is put on the heatable susceptor in the MOCVD system. The susceptor temperature is raised to about 650° C., so that the GaAs substrate 1 is heated. The ambient in the reaction tube or chamber is set to have an AsH₃ ambient. The AsH₃ ambient is maintained for about 10 minutes. The pressure in the reaction tube is about 20000 Pa. As a result, an oxide film or the like present on the surface of the GaAs substrate 1 is removed. TMG is supplied into the reaction tube, so that the GaAs layer 2 is grown.

(c) The growth pressure is reduced to about 10000 Pa in the AsH₃ ambient, and at the same time, the susceptor temperature is dropped to 350° C. At the temperature of 350° C., the supply of AsH₃ gas is stopped. TMI gas is supplied, and PH₃ gas is then supplied. As a result, the InAs buffer layer 3 and the low-temperature InP layer 4 are grown.

(d) Since the method of forming the laminated structure of layers 15, 6, 17, 8, 19, 20 and 11 conforms to the method in the first embodiment, details thereof are omitted. The susceptor temperature at the time of growing the high-temperature InGaP layer 15 and the n-type InGaAs layers 6 and 17 is 650° C. The susceptor temperature at the time of growing the p-type InGaAs layer 8 is 475° C. The susceptor temperature at the time of growing the n-type InGaP layer 19 and the n-type InGaAs layer 20 is 560° C. The susceptor temperature at the time of growing the n-type InGaAs layer 11 is 450° C.

(e) Since the forming method after the crystal growth conforms to the method in the first embodiment, explanation thereof is omitted.

A turn-on voltage is about 1.1 V in an HBT which does not have the GaAs layer 2 and the InAs buffer layer 3 and lattice-matches with the GaAs substrate 1. The turn-on voltage in an SHBT of the third embodiment is 0.9 V, thereby decreasing the voltage. Further, as compared with the case where the InAlAs layer with a composition inclination formed on the GaAs substrate 1, the element reliability is improved in an SHBT of the third embodiment. Moreover, the third embodiment refers to an SHBT, but a DHBT having the double hetero structure in which the n-type InGaAs collector layer 17 is an n-type InGaP collector layer may be used. Since the DHBT can suppress a leak current in an opposite direction, the turn-on voltage can be further decreased.

Instead of the low-temperature InP layer 4 in the SHBT of the third embodiment, a low-temperature InGaP layer can be used. Use of the low-temperature InGaP layer makes it difficult to match a mole fraction of In between the low-temperature layer and the high-temperature InGaP layer 15. When the mole fraction can be matched, however, the low-temperature InGaP layer can be a seed crystal of the high-temperature InGaP layer 15, so that monocrystalization of the high-temperature InGaP layer 15 can be accelerated. The acceleration of the monocrystalization can improve the life of the SHBT by about 20%.

(Fourth Embodiment)

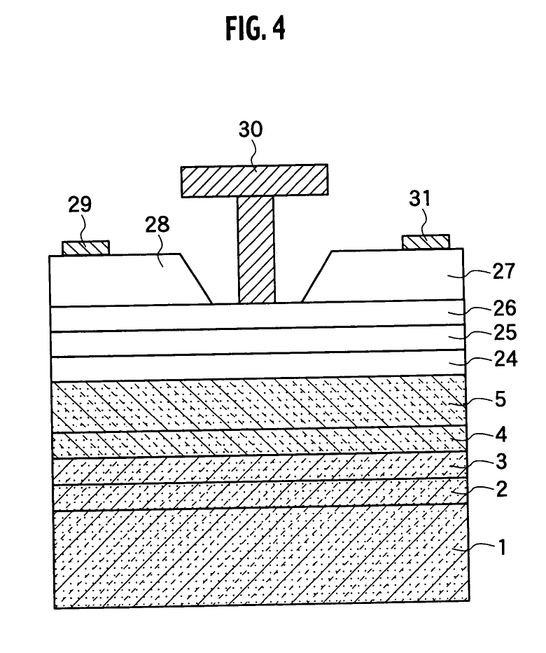

In a high electron mobility transistor (HEMT) of a fourth embodiment of the present invention, as shown in FIG. 4, the GaAs layer 2, the InAs buffer layer 3, the low-temperature grown InP layer 4, the high-temperature grown InP layer 5, an undoped InGaAs electron transit layer 24, an n-type InP electron supply layer 25, an undoped InP Schottky layer 26, n-type InGaAs ohmic contact layers 27 and 28 are laminated in the stated order on the semi-insulating GaAs substrate 1.

The thickness of the GaAs layer 2 is about 50 nm. The thickness of the InAs buffer layer 3 is about 1 nm. The thickness of the low-temperature grown InP layer 4 is 20 nm. The thickness of the high-temperature grown InP layer 5 is 1 μm. The mole fraction of In in the undoped InGaAs electron transit layer 24 is 53%. The layer 24 has a thickness of 20 nm. The thickness of the n-type InP electron supply layer 25 is 30 nm, and the carrier concentration is 5×10¹⁷ cm⁻³. The thickness of the undoped InP Schottky layer 26 is 10 nm. The mole fraction of In in the n-type InGaAs ohmic contact layers 27 and 28 is 53%. The thickness of the layers 27 and 28 is 20 nm, and the carrier concentration is 2×10¹⁸ cm⁻³.

A source electrode 29 is provided on the n-type InGaAs ohmic contact layer 28. A drain electrode 31 is provided on the n-type InGaAs ohmic contact layer 27. A gate electrode 30 is provided on the undoped InP Schottky layer 28.

With such a structure, an InP-type HEMT having excellent high-frequency characteristics can be formed on the comparatively inexpensive GaAs substrate 1.

For the HEMT of the fourth embodiment, a combination of the n-type InP electron supply layer 25 and the undoped InGaAs electron transit layer 24 has been explained. As another combination, the InGaP layer can be used as an electron supply layer, and the InGaAs layer which approximately lattice-matches with the InGaP layer can be used as an electron transit layer. The InGaP layer is used as the electron supply layer, thereby decreasing the mole fraction of In in the InGaAs electron transit layer. Since alloy dispersion can be suppressed, mobility can be increased.

(Fifth Embodiment)

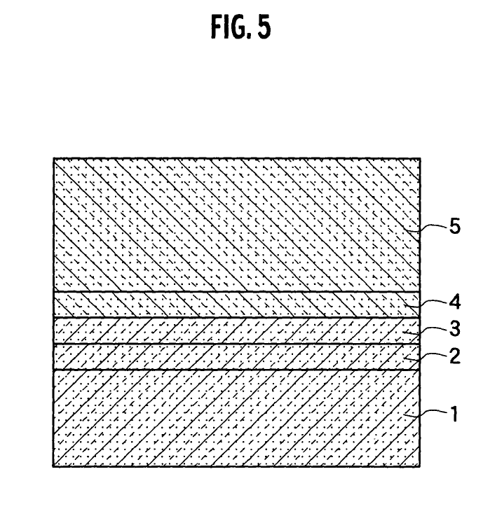

In a wafer of a fifth embodiment of the present invention, as shown in FIG. 5, the GaAs layer 2, the InAs buffer layer 3, the low-temperature grown InP layer 4, and the high-temperature grown InP layer 5 are multilayer in the stated order on the semi-insulating GaAs substrate 1. The thickness of the GaAs layer 2 is about 50 nm. The thickness of the InAs buffer layer 3 is about 1 nm. The thickness of the low-temperature grown InP layer 4 is 20 nm. The thickness of the high-temperature grown InP layer 5 is 1 μm.

In a wafer forming method in the fifth embodiment, the layers 2 to 5 are grown by MOCVD.

(a) The GaAs substrate 1 is placed on the heatable susceptor in the MOCVD system.

(b) At the time of growing the GaAs layer 2, the susceptor temperature is raised to 650° C., so that the GaAs substrate 1 is heated.

(c) The susceptor temperature is dropped to 350° C. at the time of growing the InAs buffer layer 3 and the low-temperature grown InP layer 4, so that the GaAs substrate 1 is heated.

(d) The susceptor temperature is raised to 560° C. at the time of growing the high-temperature InP layer 5, so that the GaAs substrate 1 is heated.

The high-temperature grown InP layer 5 in the wafer of the fifth embodiment and the layer 5 in a wafer without the InAs buffer layer 3 will be compared and evaluated. The resistivity in the wafer of the fifth embodiment is larger by 30% as compared with the wafer without the InAs buffer layer 3. The carrier concentration of the wafer of the fifth embodiment is lower by 30%. A full width at half maximum (FWHM) of X-ray diffraction of the wafer of the fifth embodiment is narrower by 30%. In a similar manner, all evaluation items ware improved.

(Sixth Embodiment)

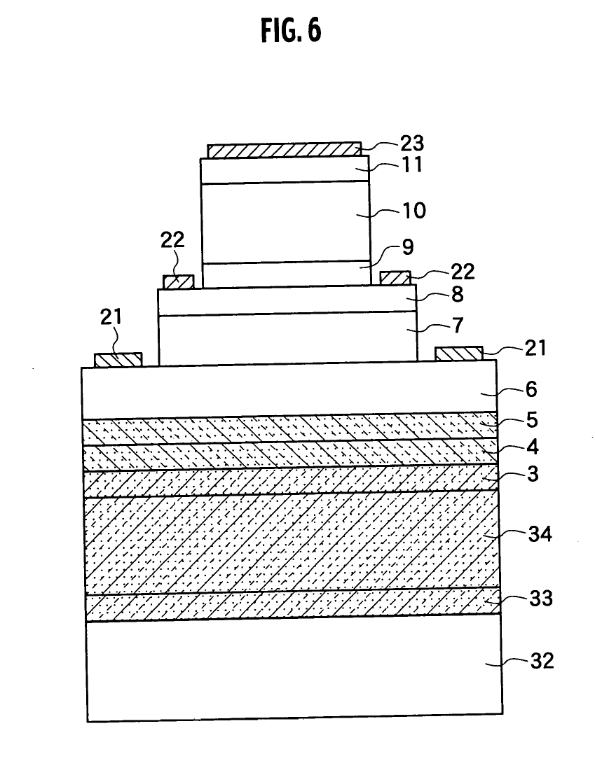

In a DHBT according to a sixth embodiment of the present invention, as shown in FIG. 6, a GaAs buffer layer 33, a GaAs layer 34, the InAs buffer layer 3, the low-temperature grown InP layer 4, the high-temperature grown InP layer 5, the n-type InGaAs collector contact layer 6, the undoped InP collector layer 7, the p-type InGaAs base layer 8, the n-type InP emitter layer 9, the n-type InP emitter contact layer 10, and the n-type InGaAs emitter contact layer 11 are multilayer in the stated order on a silicon (Si) substrate 32.

The thickness of the GaAs buffer layer 33 is 0.1 μm. The thickness of the GaAs layer 34 is 2 μm. The thickness of the InAs buffer layer 3 is about 1 nm. The thickness of the low-temperature grown InP layer 4 is 20 nm. The thickness of the high-temperature grown InP layer 5 is 0.5 μm. The thickness and the carrier concentration of the layers 6 to 11 are equal to the same layers the first embodiment. The arrangements of the collector electrode 21, the base electrode 22 and the emitter electrode 23 are the same as in the first embodiment.

In a DHBT of the sixth embodiment, a life is equivalent to that of the DHBT in the first embodiment can be achieved. Thus, an HBT with a long life can be formed on the inexpensive Si substrate 32.

The DHBT fabricating method of the sixth embodiment is explained below.

(a) The layers 33, 34 and 3 to 11 are grown on the Si substrate 32 by MOCVD. Source materials that are used for the growth are the same as in the first embodiment.

(b) The Si substrate 32 is placed on the heatable susceptor in the MOCVD system that can be heated.

(c) The susceptor temperature is raised to about 650° C. The ambient in the reaction tube or chamber is set to an AsH₃ ambient for about 10 minutes. The pressure in the reaction tube is set to about 20000 Pa.

(d) TMG is supplied into the reaction tube. The GaAs buffer layer 33 is grown. Further, supply of TMG gas is increased and the GaAs layer 34 is grown.

(e) The susceptor temperature is dropped to 350° C. in the AsH₃ ambient. At the susceptor temperature of 350° C., the supply of AsH₃ gas is stopped. TMI gas is supplied, and PH₃ gas is supplied next. As a result, the InAs buffer layer 3 and the low-temperature InP layer 4 are grown.

(f) The layers 5 to 11 are grown in a similar manner as in the first embodiment.

(g) Forming the collector electrode 21, the emitter electrode 23, and the base electrode 22, and dicing and packaging of each semiconductor device is carried out in a similar manner as in the first embodiment.

As explained above, according to the sixth embodiment, an HBT, having the InGaAs base layer 8 and operating at a low voltage, can be provided on the inexpensive, large diameter Si substrate 32.

(Seventh Embodiment)

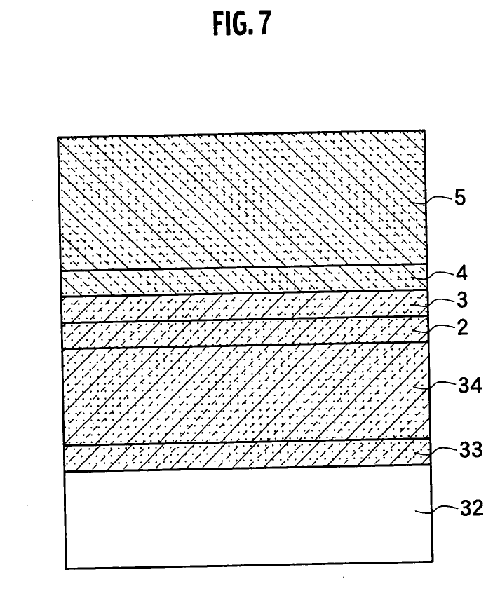

In a wafer according to the seventh embodiment of the present invention, as shown in FIG. 7, the GaAs buffer layer 33, the GaAs layer 34, the GaAs buffer layer 2, the InAs buffer layer 3, the low-temperature grown InP layer 4, and the high-temperature grown InP layer 5 are multilayer in the stated order on the Si substrate 32. The thickness of the GaAs buffer layer 33 is 0.1 μm. The thickness of the GaAs layer 34 is 2 μm. The thickness of the GaAs buffer layer 2 is 40 nm. The thickness of the InAs buffer layer 3 is about 1 nm. The thickness of the low-temperature grown InP layer 4 is 20 nm. The thickness of the high-temperature grown InP layer 5 is 0.5 μm.

A wafer fabricating method of the seventh embodiment is the same as the growth method of the layers 33, 34 and 2 to 5 in the fabricating method of the sixth embodiment.

In the wafer of the seventh embodiment, the resistivity of the high-temperature grown InP layer 5 is equivalent to the wafer of the fifth embodiment. The half-value width of X-ray diffraction is equal to that of the wafer of the fifth embodiment.

Various modifications will become possible for those skilled in the art after receiving the teachings of the present disclosure without departing from the scope thereof.

What is claimed is:

1. A semiconductor device comprising:
a gallium arsenide substrate;
an indium arsenide layer disposed on the gallium arsenide substrate;
a semiconductor layer disposed over the indium arsenide layer and having a lattice constant larger than that of the gallium arsenide substrate and smaller than that of the indium arsenide layer; and
a semiconductor section disposed on the semiconductor layer, lattice-matching with the semiconductor layer and configured as a transistor.

2. The semiconductor device as claimed in claim 1, wherein the semiconductor layer is an indium gallium phosphide layer.

3. The semiconductor device as claimed in claim 1, wherein the semiconductor layer is an indium phosphide layer.

4. A wafer comprising:
a gallium arsenide substrate;
an indium arsenide layer disposed on the gallium arsenide substrate; and
a semiconductor layer disposed over the indium arsenide layer and having a lattice constant larger than that of the gallium arsenide substrate and smaller than that of the indium arsenide layer.

5. The wafer as claimed in claim 4, wherein the semiconductor layer is an indium gallium phosphide layer.

6. The wafer as claimed in claim 4, wherein the semiconductor layer is an indium phosphide layer.

7. A wafer comprising:
a silicon substrate;
a gallium arsenide layer disposed over the silicon substrate;
an indium arsenide layer disposed on the gallium arsenide layer; and
a semiconductor layer disposed over the indium arsenide layer and having a lattice constant larger than that of the gallium arsenide layer and smaller than that of the indium arsenide layer.

8. The wafer as claimed in claim 7, wherein the semiconductor layer is an indium gallium phosphide layer.

9. The wafer as claimed in claim 7, wherein the semiconductor layer is an indium phosphide layer.

10. A method of making a wafer comprising:
forming an indium arsenide layer on a gallium arsenide substrate at a first substrate temperature;
forming a first semiconductor layer having a first lattice constant larger than that of the gallium arsenide substrate and smaller than that of the indium arsenide layer on the indium arsenide layer at the first substrate temperature; and
forming a second semiconductor layer having a second lattice constant larger than that of the gallium arsenide substrate and smaller than that of the indium arsenide layer on the first semiconductor layer at a second substrate temperature higher than the first substrate temperature.

11. The method of making a wafer as claimed in claim 10, wherein the first semiconductor layer is an indium gallium phosphide layer or an indium phosphide layer.

12. The method of making a wafer as claimed in claim 10, wherein the second semiconductor layer is an indium gallium phosphide layer or an indium phosphide layer.

13. A method of making a semiconductor device comprising:
forming an indium arsenide layer on a gallium arsenide substrate at a first substrate temperature;
forming a first semiconductor layer having a first lattice constant larger than that of the gallium arsenide substrate and smaller than that of the indium arsenide layer on the indium arsenide layer at the first substrate temperature;
forming a second semiconductor layer having a second lattice constant larger than that of the gallium arsenide substrate and smaller than that of the indium arsenide layer on the first semiconductor layer at a second substrate temperature higher than the first substrate temperature; and
forming a semiconductor section on the second semiconductor layer lattice-matching with the second semiconductor layer and configured as a transistor.

14. A method of making a semiconductor layer comprising:
forming an indium arsenide layer on a gallium arsenide substrate at a first substrate temperature;
forming a first semiconductor layer having a first lattice constant larger than that of the gallium arsenide substrate and smaller than that of the indium arsenide layer on the indium arsenide layer at the first substrate temperature; and
forming a second semiconductor layer having a second lattice constant larger than that of the gallium arsenide substrate and smaller than that of the indium arsenide layer on the first semiconductor layer at a second substrate temperature higher than the first substrate temperature.
